(19) United States
(12) Patent Application Publication
(10) Pub. No.: US 2025/0088169 A1
(43) Pub. Date: Mar. 13, 2025

(54) STRUCTURE OF LONGITUDINAL LEAKY SURFACE ACOUSTIC WAVE (LL-SAW) RESONATOR AND FILTER

(71) Applicant: SHANGHAI INSTITUTE OF MICROSYSTEMS AND INFORMATION TECHNOLOGY, CHINESE ACADEMY OF SCIENCES, Shanghai (CN)

(72) Inventors: Xin Ou, Shanghai (CN); Pengcheng Zheng, Shanghai (CN); Shibin Zhang, Shanghai (CN); Jinbo Wu, Shanghai (CN); Liping Zhang, Shanghai (CN)

(21) Appl. No.: 18/956,018

(22) Filed: Nov. 22, 2024

Related U.S. Application Data
(63) Continuation-in-part of application No. PCT/CN2023/098973, filed on Jun. 7, 2023.

(30) Foreign Application Priority Data
Jun. 21, 2022 (CN) 202210732455.7

(51) Int. Cl. H03H 9/02; H03H 9/145; H03H 9/25; H03H 9/64

(52) U.S. Cl. CPC H03H 9/02716; H03H 9/02559; H03H 9/02834; H03H 9/14547; H03H 9/25; H03H 9/6483

(57) ABSTRACT

A structure of a longitudinal leaky surface acoustic wave (LL-SAW) resonator and a filter includes a substrate, a piezoelectric thin film provided on the substrate, and an electrode array provided on the piezoelectric thin film, where the electrode array includes an interdigital transducer (IDT) array and a reflector grating electrode array; and a center distance between reflector grating electrodes in the reflector grating electrode array is less than a center distance between IDTs in the IDT array. Based on a nonstandard reflector (NSR) grating structure provided by the embodiments of the present disclosure, by reducing the center distance between the reflector grating electrodes in the reflector grating electrode array, the present disclosure can improve a reflective frequency range of the reflector grating electrode array, thereby suppressing a spurious mode of the LL-SAW, and improving performance of the LL-SAW resonator.

### CROSS REFERENCE TO RELATED APPLICATIONS

The present application is a Continuation-In-Part Application of PCT Application No. PCT/CN2023/098973 filed on Jun. 7, 2023, which claims the benefit of Chinese Patent Application No. 202210732455.7 filed on Jun. 21, 2022. All the above are hereby incorporated by reference in their entirety.

### TECHNICAL FIELD

The present disclosure relates to the technical field of preparation of heterogeneous integrated devices, and in particular, to a structure of a longitudinal leaky surface acoustic wave (LL-SAW) resonator and a filter.

### BACKGROUND

The existing surface acoustic wave (SAW) resonator is a double-layer structure integrated with a piezoelectric thin film and a silicon carbide (SiC) substrate. Parallel interdigital transducers (IDTs) are provided on the piezoelectric material. Meanwhile, reflector grating electrode arrays are respectively provided at a left side and a right side of the IDTs. Because of a high acoustic velocity of the SiC substrate, this structure can effectively excite and confine acoustic field energy of the LL-SAW to realize the high-performance LL-SAW resonator. A center distance between the IDTs is the same as a center distance between reflector grating electrodes. However, the LL-SAW is prone to strong scattering at a junction between the IDT and the reflector grating electrode to cause a spurious mode, which seriously affects flatness of a passband of the filter.

### SUMMARY

In order to solve the problem that a structure of the existing resonator is prone to a spurious mode, an embodiment of the present disclosure provides a structure of an LL-SAW resonator, including:
a substrate, where the substrate is made of SiC;
a piezoelectric thin film provided on the substrate, where the piezoelectric thin film is made of lithium niobate (LiNbO₃) or lithium tantalate (LiTaO₃); and
an electrode array provided on the piezoelectric thin film, where the electrode array includes an IDT array and a reflector grating electrode array, and a center distance between reflector grating electrodes in the reflector grating electrode array is less than a center distance between IDTs in the IDT array.

Further, a ratio of the center distance between the reflector grating electrodes in the reflector grating electrode array to the center distance between the IDTs in the IDT array falls into a range of [0.825, 1).

Further, the reflector grating electrode array includes a first reflector grating electrode array and a second reflector grating electrode array;
the first reflector grating electrode array is provided at one side of the IDT array, and the second reflector grating electrode array is provided at the other side of the IDT array;
a center distance between reflector grating electrodes in the first reflector grating electrode array is the same as a center distance between reflector grating electrodes in the second reflector grating electrode array; or,
the center distance between the reflector grating electrodes in the first reflector grating electrode array is different from the center distance between the reflector grating electrodes in the second reflector grating electrode array.

Further, the first reflector grating electrode array includes a first reflector grating electrode sub-array and a second reflector grating electrode sub-array;
the second reflector grating electrode array includes a third reflector grating electrode sub-array and a fourth reflector grating electrode sub-array;
a center distance between reflector grating electrodes in the first reflector grating electrode sub-array is different from a center distance between reflector grating electrodes in the second reflector grating electrode sub-array; and
a center distance between reflector grating electrodes in the third reflector grating electrode sub-array is different from a center distance between reflector grating electrodes in the fourth reflector grating electrode sub-array.

Further, the center distance between the reflector grating electrodes in the first reflector grating electrode sub-array, the center distance between the reflector grating electrodes in the second reflector grating electrode sub-array, the center distance between the reflector grating electrodes in the third reflector grating electrode sub-array, and the center distance between the reflector grating electrodes in the fourth reflector grating electrode sub-array are different.

Further, there is a slant angle between an extension direction of the IDT array and a normal direction of the electrode array, as well as between an extension direction of the reflector grating electrode array and the normal direction of the electrode array; and the slant angle is less than a preset threshold; and the preset threshold is 10°.

Further, the structure further includes:
a dielectric layer provided on the substrate,
where the dielectric layer is made of silicon oxide (SiOₓ), silicon nitride (Si₃N₄), aluminum nitride (AlN) or aluminum oxide (Al₂O₃).

Further, the structure further includes:
a dielectric layer provided on the electrode array,
where the dielectric layer is made of SiOₓ, Si₃N₄, AlN or Al₂O₃.

Further, the structure further includes:
a first dielectric layer provided on the electrode array; and
a second dielectric layer provided on the substrate,
where the first dielectric layer is made of SiOₓ, Si₃N₄, AlN or Al₂O₃; and
the second dielectric layer is made of the SiOₓ, the Si₃N₄, the AlN or the Al₂O₃.

Accordingly, an embodiment of the present disclosure provides a filter, including a plurality of resonators, where the resonators each are provided with the structure of an LL-SAW resonator;
the plurality of resonators are cascaded, bridged or coupled based on a preset topological structure; or,
the plurality of resonators are cascaded or bridged with an external capacitor element and an external inductor element.

The embodiments of the present disclosure have following beneficial effects:

According to the structure of an LL-SAW resonator and the filter provided by the embodiments of the present disclosure, the structure of an LL-SAW resonator includes a substrate, a piezoelectric thin film provided on the substrate, and an electrode array provided on the piezoelectric thin film. The electrode array includes an IDT array and a reflector grating electrode array. A center distance between reflector grating electrodes in the reflector grating electrode array is less than a center distance between IDTs in the IDT array. Based on a nonstandard reflector (NSR) grating structure provided by the embodiments of the present disclosure, by reducing the center distance between the reflector grating electrodes in the reflector grating electrode array, the present disclosure can improve a reflective frequency range of the reflector grating electrode array, thereby suppressing a spurious mode of the LL-SAW, and improving performance of the resonator.

### BRIEF DESCRIPTION OF THE DRAWINGS

To describe the technical solutions in the embodiments of the present disclosure or in the prior art more clearly, the following briefly describes the accompanying drawings required for describing the embodiments or the prior art. Apparently, the accompanying drawings in the following description show some embodiments of the present disclosure, and a person of ordinary skill in the art may still derive other accompanying drawings from these accompanying drawings without creative efforts.

FIG. 1 is a first schematic cross-sectional view of a resonator according to an embodiment of the present disclosure;

FIG. 2 is a first schematic top view of a resonator according to an embodiment of the present disclosure;

FIG. 3 is a response curve of an LL-SAW resonator on a LiNbO₃ single crystal and a response curve of an LL-SAW resonator on a LiNbO₃ thin film/silicon (Si) substrate according to an embodiment of the present disclosure;

FIG. 4 (a) is a simulated performance chart of an LL-SAW resonator on a LiNbO₃ thin film/SiC substrate according to an embodiment of the present disclosure;

FIG. 4 (b) is a simulated performance chart of an LL-SAW resonator on a LiNbO₃ thin film/SiC substrate according to an embodiment of the present disclosure;

FIG. 4 (c) is a simulated performance chart of an LL-SAW resonator on a LiNbO₃ thin film/SiC substrate according to an embodiment of the present disclosure;

FIG. 5 is a schematic structural view of a filter according to an embodiment of the present disclosure;

FIG. 6 is a simulated performance chart of an LL-SAW filter using a standard reflector (SR) grating structure and based on a LiNbO₃ thin film/SiC substrate according to an embodiment of the present disclosure;

FIG. 7 is a simulated performance chart of an LL-SAW filter using an NSR grating structure and based on a LiNbO₃ thin film/SiC substrate according to an embodiment of the present disclosure;

FIG. 8 is a second schematic cross-sectional view of a resonator according to an embodiment of the present disclosure;

FIG. 9 is a third schematic cross-sectional view of a resonator according to an embodiment of the present disclosure;

FIG. 10 is a fourth schematic cross-sectional view of a resonator according to an embodiment of the present disclosure;

FIG. 11 is a second schematic top view of a resonator according to an embodiment of the present disclosure; and

FIG. 12 is a schematic structural view of another filter according to an embodiment of the present disclosure.

In the figures:
100—substrate, 200—piezoelectric thin film, 300—electrode array, 310—IDT array, 320—reflector grating electrode array, 321—first reflector grating electrode array, 322—second reflector grating electrode array, 321A—first reflector grating electrode sub-array, 321B—second reflector grating electrode sub-array, 322A—third reflector grating electrode sub-array, 322B—fourth reflector grating electrode sub-array, 400—dielectric layer, 410—first dielectric layer, and 420—second dielectric layer.

### DETAILED DESCRIPTION

To make the objectives, technical solutions, and advantages of the present disclosure clearer, the embodiments of the present disclosure will be further described in detail with reference to the accompanying drawings. Apparently, the embodiments described are merely some rather than all of the embodiments of the present disclosure. All other embodiments obtained by those of ordinary skill in the art based on the embodiments of the present disclosure without creative efforts should fall within the protection scope of the present disclosure.

As used herein, “an embodiment” refers to a particular feature, structure, or characteristic that may be included in at least one implementation of the present disclosure. In the description of the embodiments of the present disclosure, it should be understood that the terms such as “first”, “second”, “third”, and “fourth” are used merely for a descriptive purpose, and should not be construed as indicating or implying a relative importance, or implicitly indicating a quantity of indicated technical features. Therefore, the features defined by the terms such as “first”, “second”, “third”, and “fourth” may explicitly or implicitly include one or more of the features. Further, the terms such as “first”, “second”, “third”, and “fourth” are intended to distinguish between similar objects, rather than to necessarily describe a specific order or sequence. It should be understood that the data used in such a manner may be exchanged under proper conditions to make it possible for the described embodiments of the present disclosure to be implemented in a sequence except those illustrated or described herein. Moreover, the terms “include”, “have”, “is/are”, and any variations thereof mean to cover non-exclusive inclusion.

In response to the new-generation mobile communication technology, a high-performance radio-frequency (RF) front-end filter with a high frequency and a large bandwidth is required urgently. The SAW filter has an operating frequency of f=v/(2×P). This operating frequency is directly proportional to an acoustic velocity v of an acoustic wave propagated in the piezoelectric material, but inversely proportional to a center distance P between IDTs. According to existing solutions, the operating frequency of the filter is improved by reducing a linewidth in photoetching, namely reducing the center distance P between the IDTs. However, the frequently-used acoustic waves in the SAW devices include a shear horizontal surface acoustic wave (SH-SAW), a Rayleigh surface acoustic wave (Rayleigh-SAW), and a longitudinal leaky surface acoustic wave (LL-SAW). The former two waves have an acoustic velocity of less than 4,000 m/s, but the latter has an acoustic velocity of greater than 6,000 m/s. Hence, the LL-SAW filter is promising to realize a higher operating frequency at the same linewidth.

A SAW resonator is a basic unit of the SAW filter, and its performance directly affects performance of the constructed filter. The LL-SAW resonator based on a LiNbO₃ or LiTaO₃ piezoelectric single-crystal material has a low quality factor (Q) (which is 2π times a ratio of stored energy to consumed energy in each cycle of the resonator), and thus cannot be applied to the filter. Meanwhile, for multilayered piezoelectric heterogeneous substrate structures, due to a low velocity of the SAW on a Si substrate, a quartz substrate and the like, if the acoustic field energy of the LL-SAW is confined in the piezoelectric thin film, a Bragg reflecting layer is to be provided between the piezoelectric thin film and the substrate to cause a complicated structure.

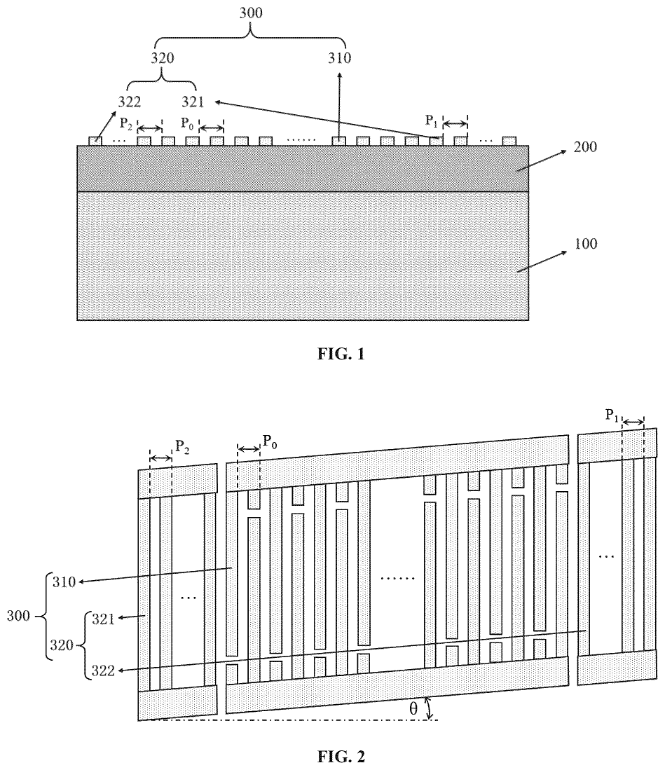

The following describes a specific embodiment of a structure of an LL-SAW resonator in the present disclosure. FIG. 1 is a first schematic cross-sectional view of a resonator according to an embodiment of the present disclosure. FIG. 2 is a first schematic top view of a resonator according to an embodiment of the present disclosure. This specification provides a composition structure as shown in the embodiments or in the accompanying drawings, but more or fewer modules or components may be included based on conventional or non-creative efforts. The composition structure listed in the embodiments is only one of numerous composition structures and is not a unique composition structure. In actual execution, the composition structure shown in the embodiments or in the accompanying drawings may be followed.

Specifically, as shown in FIG. 1 and FIG. 2, the structure of an LL-SAW resonator may include a substrate 100, a piezoelectric thin film 200 provided on the substrate 100, and an electrode array 300 provided on the piezoelectric thin film 200. The electrode array 300 may include an IDT array 310 and a reflector grating electrode array 320. A center distance between reflector grating electrodes in the reflector grating electrode array 320 is less than a center distance between IDTs in the IDT array 310. By reducing the distance between the reflector grating electrodes in the reflector grating electrode array 320, a reflective frequency range of the reflector grating electrode array 320 can be improved, thereby suppressing a spurious mode of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency.

In the embodiment of the present disclosure, a ratio of the center distance P between the reflector grating electrodes in the reflector grating electrode array 320 to the center distance P₀ between the IDTs in the IDT array 310 may fall into a range of [0.825, 1).

In the embodiment of the present disclosure, electrodes in the electrode array 300 may have a thickness of greater than 60 nm and less than 0.05P₀. A metal thickness of the IDT array 310 may be different from a metal thickness of the reflector grating electrode array 320.

In the embodiment of the present disclosure, the reflector grating electrode array 320 may include a first reflector grating electrode array 321 and a second reflector grating electrode array 322. The first reflector grating electrode array 321 may be provided at one side of the IDT array 310, and the second reflector grating electrode array 322 may be provided at the other side of the IDT array 310. A center distance P₁ between reflector grating electrodes in the first reflector grating electrode array 321 may be less than the center distance P₀ between the IDTs in the IDT array 310. A center distance P₂ between reflector grating electrodes in the second reflector grating electrode array 322 may be less than the center distance P₀ between the IDTs in the IDT array 310. Optionally, a ratio of the center distance P₁ between the reflector grating electrodes in the first reflector grating electrode array 321 to the center distance P₀ between the IDTs in the IDT array 310 may fall into the range of [0.825, 1). A ratio of the center distance P₂ between the reflector grating electrodes in the second reflector grating electrode array 322 to the center distance P₀ between the IDTs in the IDT array 310 may fall into the range of [0.825, 1). For example, the ratio of the center distance P₁ between the reflector grating electrodes in the first reflector grating electrode array 321 to the center distance P₀ between the IDTs in the IDT array 310 may be 0.975. The ratio of the center distance P₁ between the reflector grating electrodes in the first reflector grating electrode array 321 to the center distance P₀ between the IDTs in the IDT array 310 may be 0.95. The ratio of the center distance P₂ between the reflector grating electrodes in the second reflector grating electrode array 322 to the center distance P₀ between the IDTs in the IDT array 310 may be 0.975. The ratio of the center distance P₂ between the reflector grating electrodes in the second reflector grating electrode array 322 to the center distance P₀ between the IDTs in the IDT array 310 may be 0.95.

In an optional implementation, the center distance between the reflector grating electrodes in the first reflector grating electrode array 321 may be the same as the center distance between the reflector grating electrodes in the second reflector grating electrode array 322, namely P₁=P₂. The center distance between the reflector grating electrodes in the first reflector grating electrode array 321 may be different from the center distance between the reflector grating electrodes in the second reflector grating electrode array 322, namely P₁≠P₂.

In an optional implementation, as shown in FIG. 2, the IDTs in the IDT array 310 may have different lengths. The IDT array 310 may include an extremely short IDT (also referred to as a pseudo IDT) located in a same length direction as each of the IDTs. This can increase the Q.

In an optional implementation, the IDT array 310 and the reflector grating electrode array 320 may be parallel arranged on the piezoelectric thin film 200. The first reflector grating electrode array 321 and the second reflector grating electrode array 322 may be respectively provided at a left side and a right side of the IDT array 310. The reflector grating electrode array 320 may be shorted, and may also be disconnected. There is a slant angle θ between an extension direction of the IDT array 310 and a normal direction of the electrode array 300, as well as between an extension direction of the reflector grating electrode array 320 and the normal direction of the electrode array. The slant angle may be less than a preset threshold. Optionally, the preset threshold may be 10°. The IDT array 310 and the reflector grating electrode array 320 are provided on the piezoelectric thin film 200 at the slant angle, which can increase the Q and suppress the spurious wave.

In the embodiment of the present disclosure, the substrate 100 may be made of SiC, and the piezoelectric thin film 200 may be made of LiNbO₃ and LiTaO₃. Optionally, the LiTaO₃ thin film and the LiTaO₃ thin film may have a thickness in a range of [200 nm, 800 nm].

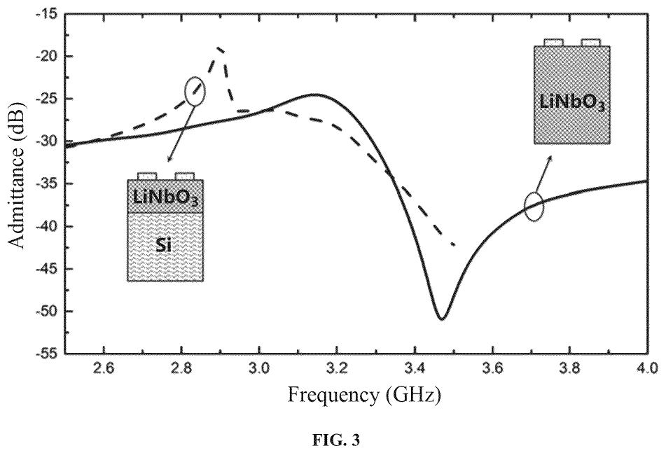

FIG. 3 is a response curve of an LL-SAW resonator on a LiNbO₃ single crystal and a response curve of an LL-SAW resonator on a LiNbO₃ thin film/Si substrate according to an embodiment of the present disclosure. The solid line may represent the response curve of the LL-SAW resonator on the LiNbO₃ single crystal. The dashed line may represent the response curve of the LL-SAW resonator on the LiNbO₃ thin film/Si substrate. The center distance between the reflector grating electrodes in the reflector grating electrode array 320 may be less than the center distance between the IDTs in the IDT array 310. As can be seen from FIG. 3, both the LL-SAW resonator on the LiNbO₃ single crystal and the LL-SAW resonator on the LiNbO₃ thin film/Si substrate cannot realize the high Q or the high admittance ratio (AR) (a difference between a highest point and a lowest point of an admittance). Thus, the problem to be solved by the embodiment of the present disclosure is to make the LL-SAW device on the LiTaO₃ thin film/SiC substrate or the LL-SAW device on the LiNbO₃ thin film/SiC substrate unique.

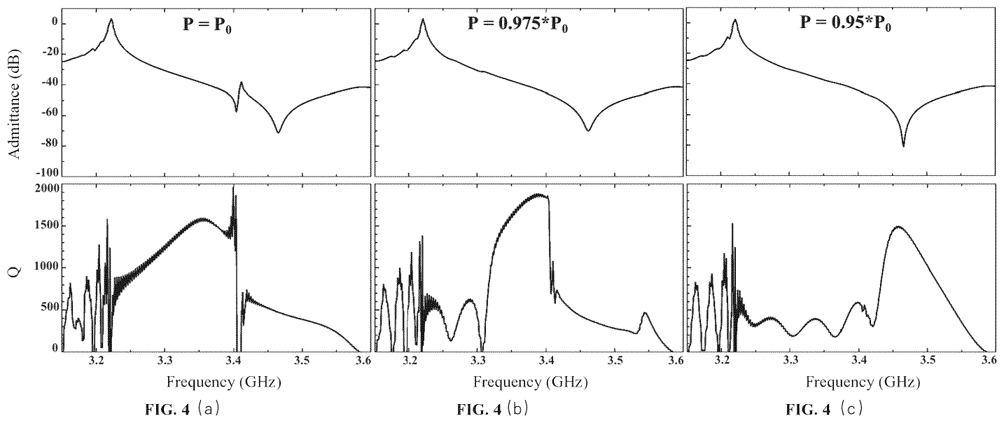

FIG. 4 (a), FIG. 4 (b), and FIG. 4 (c) are simulated performance charts of an LL-SAW resonator on a LiNbO₃ thin film/SiC substrate according to an embodiment of the present disclosure. Simulation parameters are as follows: The substrate 100 is made of SiC. The piezoelectric thin film 200 is made of 500 nm X-cut LiNbO₃. The IDTs are made of 100 nm aluminum (Al). The center distance between the IDTs is P₀=1 μm. The metallization ratio is 50%. FIG. 4 (a) illustrates an admittance response curve and a Q curve of the resonator if P₁=P₂=P₀. FIG. 4 (b) illustrates an admittance response curve and a Q curve of the resonator if P₁=P₂=0.975P₀. FIG. 4 (c) illustrates an admittance response curve and a Q curve of the resonator if P₁=P₂=0.95P₀. As can be seen from FIG. 4 (a), if the SR grating electrode array (P₁=P₂=P₀) is used, although the resonator has the AR of 60 dB or more, a spurious mode occurs at 3.4 GHZ, and a “collapse” occurs correspondingly on the Q curve. This indicates that the acoustic energy is leaked seriously. If the structure of the resonator provided by the embodiment of the present disclosure is used, the spurious wave disappears by reducing the center distance between the reflector grating electrodes in the reflector grating electrode array 320. Meanwhile, as the center distance P between the reflector grating electrodes in the reflector grating electrode array 320 is reduced, the highest point of the Q curve shifts to a higher frequency continuously. By reducing the center distance between the reflector grating electrodes in the reflector grating electrode array 320, the spurious mode in the SR structure can be suppressed. However, a high-Q frequency range of the resonator is narrower. As shown in FIG. 4 (c), the resonator shows a high Q only in a range of 3.45-3.55 GHz.

With the structure of the resonator provided by the embodiment of the present disclosure, by reducing the center distance between the reflector grating electrodes in the reflector grating electrode array 320, a reflective frequency range of the reflector grating electrode array 320 can be improved, thereby suppressing the spurious mode of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency. The IDT array 310 and the reflector grating electrode array 320 are provided on the piezoelectric thin film 200 at the slant angle, which can increase the Q and suppress the spurious wave.

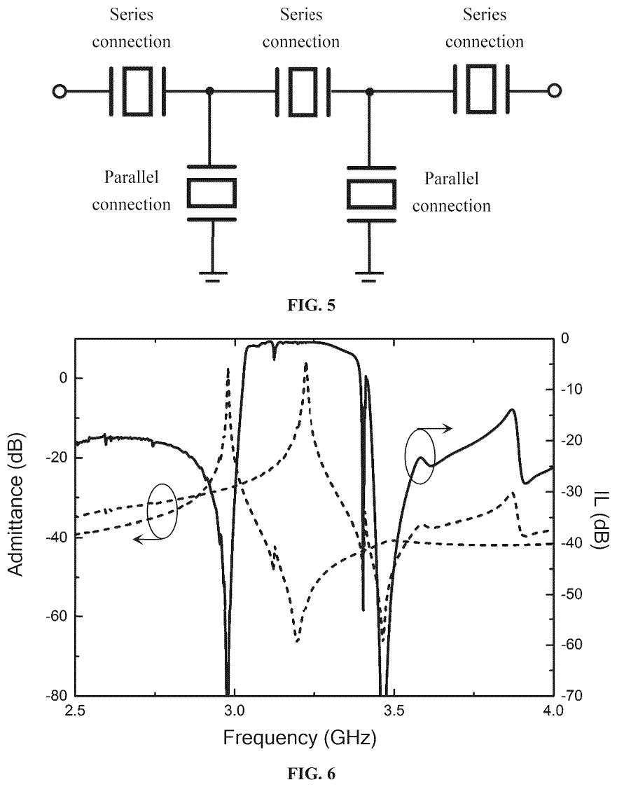

The following describes a specific embodiment of a filter provided by the present disclosure. FIG. 5 is a schematic structural view of a filter according to an embodiment of the present disclosure. The filter may include a plurality of resonators. The resonators each may be provided with the structure shown in FIG. 1. The plurality of resonators may be electrically connected based on a preset topological structure to form the filter. The preset topological structure includes a ladder type, a transversal, a lattice type, etc. As shown in FIG. 5, the plurality of resonators may be cascaded based on the preset topological structure. An operating frequency of a series resonator is higher than an operating frequency of a parallel resonator. Hence, there is a need to assume that a resonant frequency of the series resonator, namely the highest point of the admittance, is basically the same as an antiresonant frequency of the parallel resonator.

FIG. 6 is a simulated performance chart of an LL-SAW filter using an SR grating structure and based on a LiNbO₃ thin film/SiC substrate according to an embodiment of the present disclosure. The dashed lines respectively represent an admittance curve of a series resonator and an admittance curve of a parallel resonator in the filter, both of which respectively show the spurious mode at 3.4 GHz and 3.15 GHz. The solid line represents an insertion loss (IL) curve of the LL-SAW filter. As can be easily seen, two huge depressions occur in a passband of the filter in case of the spurious mode of the resonator, such that the device is unavailable.

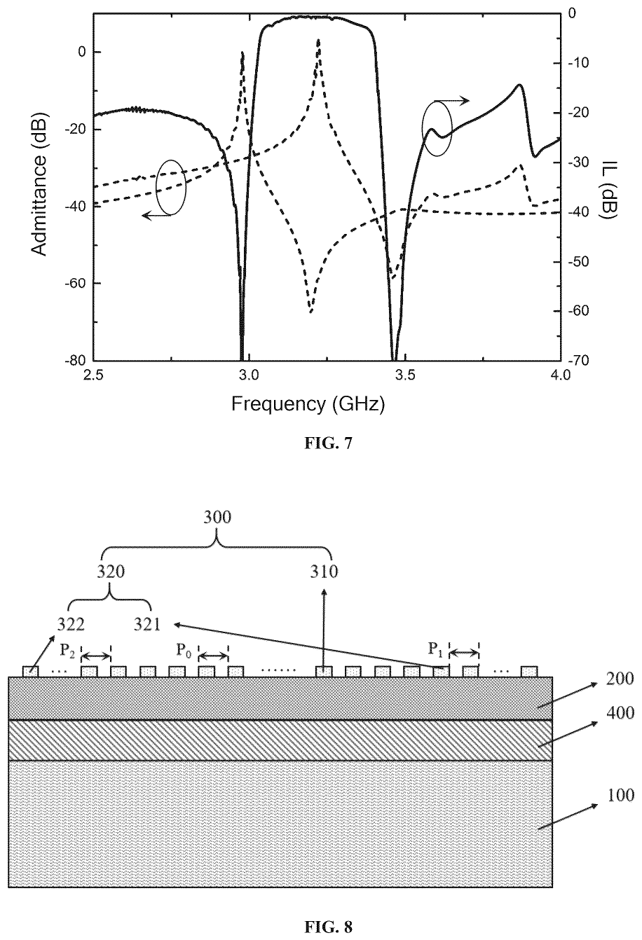

FIG. 7 is a simulated performance chart of an LL-SAW filter using an NSR grating structure and based on a LiNbO₃ thin film/SiC substrate according to an embodiment of the present disclosure. The center distance P₁ between the reflector grating electrodes in the first reflector grating electrode array 321 is the same as the center distance P₂ between the reflector grating electrodes in the second reflector grating electrode array 322, namely P₁=P₂=0.95P₀. The dashed lines respectively represent an admittance curve of a series resonator and an admittance curve of a parallel resonator in the filter. The solid line represents an IL curve of the LL-SAW filter. As can be seen, the passband of the filter is flat without a depression.

The following describes a specific embodiment of a structure of an LL-SAW resonator in the present disclosure. FIG. 8 is a second schematic structural view of a resonator according to an embodiment of the present disclosure. This specification provides a composition structure as shown in the embodiments or in the accompanying drawings, but more or fewer modules or components may be included based on conventional or non-creative efforts. The composition structure listed in the embodiments is only one of numerous composition structures and is not a unique composition structure. In actual execution, the composition structure shown in the embodiments or in the accompanying drawings may be followed.

Specifically, as shown in FIG. 8, the structure of an LL-SAW resonator may include a substrate 100, a dielectric layer 400 provided on the substrate 100, a piezoelectric thin film 200 provided on the dielectric layer 400, and an electrode array 300 provided on the piezoelectric thin film 200. The electrode array 300 may include an IDT array 310 and a reflector grating electrode array 320. A center distance between reflector grating electrodes in the reflector grating electrode array 320 is less than a center distance between IDTs in the IDT array 310. By reducing the center distance between the reflector grating electrodes in the reflector grating electrode array 320, a reflective frequency range of the reflector grating electrode array 320 can be improved, thereby suppressing a spurious mode of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency.

In the embodiment of the present disclosure, a ratio of the center distance P between the reflector grating electrodes in the reflector grating electrode array 320 to the center distance P₀ between the IDTs in the IDT array 310 may fall into a range of [0.825, 1).

In the embodiment of the present disclosure, the reflector grating electrode array 320 may include a first reflector grating electrode array 321 and a second reflector grating electrode array 322. The first reflector grating electrode array 321 may be provided at one side of the IDT array 310, and the second reflector grating electrode array 322 may be provided at the other side of the IDT array 310. A center distance P₁ between reflector grating electrodes in the first reflector grating electrode array 321 may be less than the center distance P₀ between the IDTs in the IDT array 310. A center distance P₂ between reflector grating electrodes in the second reflector grating electrode array 322 may be less than the center distance P₀ between the IDTs in the IDT array 310. Optionally, a ratio of the center distance P₁ between the reflector grating electrodes in the first reflector grating electrode array 321 to the center distance P₀ between the IDTs in the IDT array 310 may fall into the range of [0.825, 1). A ratio of the center distance P₂ between the reflector grating electrodes in the second reflector grating electrode array 322 to the center distance P₀ between the IDTs in the IDT array 310 may fall into the range of [0.825, 1).

In an optional implementation, the center distance between the reflector grating electrodes in the first reflector grating electrode array 321 may be the same as the center distance between the reflector grating electrodes in the second reflector grating electrode array 322, namely P₁=P₂. The center distance between the reflector grating electrodes in the first reflector grating electrode array 321 may be different from the center distance between the reflector grating electrodes in the second reflector grating electrode array 322, namely P₁≠P₂.

In an optional implementation, the IDT array 310 and the reflector grating electrode array 320 may be parallel arranged on the piezoelectric thin film 200. The first reflector grating electrode array 321 and the second reflector grating electrode array 322 may be respectively provided at a left side and a right side of the IDT array 310. The reflector grating electrode array 320 may be shorted, and may also be disconnected. There is a slant angle θ between an extension direction of the IDT array 310 and a normal direction of the electrode array 300, as well as between an extension direction of the reflector grating electrode array 320 and the normal direction of the electrode array. The slant angle is less than a preset threshold. Optionally, the preset threshold may be 10°. The IDT array 310 and the reflector grating electrode array 320 are provided on the piezoelectric thin film 200 at the slant angle, which can increase the Q and suppress the spurious wave.

In the embodiment of the present disclosure, the substrate 100 may be made of SiC, and the piezoelectric thin film 200 may be made of LiNbO₃ and LiTaO₃.

In the embodiment of the present disclosure, the dielectric layer 400 may be made of a nonmetal material such as SiOₓ, Si₃N₄, AlN or Al₂O₃. This can facilitate the material preparation process, and can further increase the Q of the resonator or improve the temperature stability of the device.

With the structure of the resonator provided by the embodiment of the present disclosure, by reducing the center distance between the reflector grating electrodes in the reflector grating electrode array 320, a reflective frequency range of the reflector grating electrode array 320 can be improved, thereby suppressing the spurious mode of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency. The IDT array 310 and the reflector grating electrode array 320 are provided on the piezoelectric thin film 200 at the slant angle, which can increase the Q and suppress the spurious wave. The dielectric layer 400 is provided on the substrate 100, which can further increase the Q of the resonator or improve the temperature stability of the device.

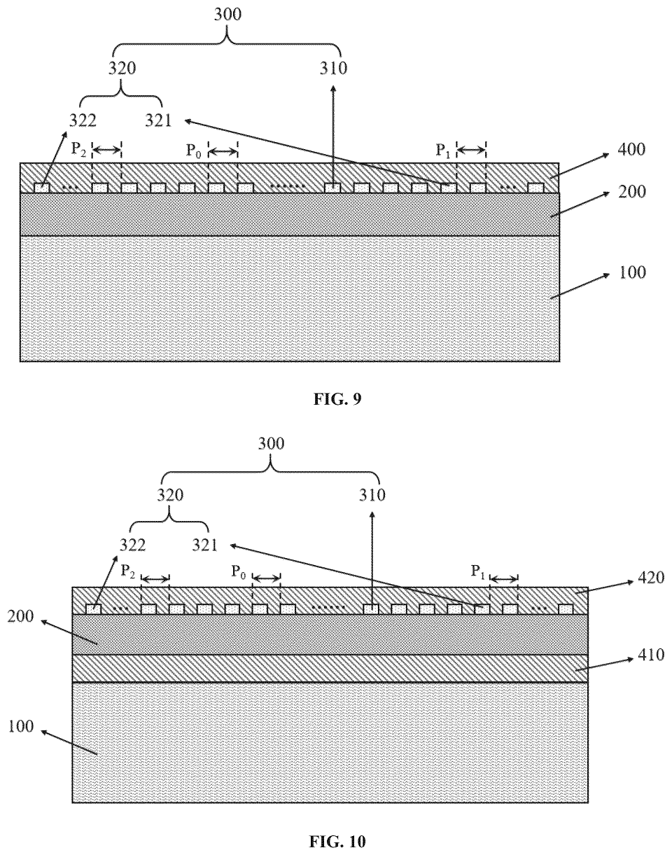

The following describes a specific embodiment of a structure of an LL-SAW resonator in the present disclosure. FIG. 9 is a third schematic structural view of a resonator according to an embodiment of the present disclosure. This specification provides a composition structure as shown in the embodiments or in the accompanying drawings, but more or fewer modules or components may be included based on conventional or non-creative efforts. The composition structure listed in the embodiments is only one of numerous composition structures and is not a unique composition structure. In actual execution, the composition structure shown in the embodiments or in the accompanying drawings may be followed.

Specifically, as shown in FIG. 9, the structure of an LL-SAW resonator may include a substrate 100, a piezoelectric thin film 200 provided on the substrate 100, an electrode array 300 provided on the piezoelectric thin film 200, and a dielectric layer 400 provided on the electrode array 300. The electrode array 300 may include an IDT array 310 and a reflector grating electrode array 320. A center distance between reflector grating electrodes in the reflector grating electrode array 320 is less than a center distance between IDTs in the IDT array 310. By reducing the center distance between the reflector grating electrodes in the reflector grating electrode array 320, a reflective frequency range of the reflector grating electrode array 320 can be improved, thereby suppressing a spurious mode of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency.

In the embodiment of the present disclosure, a ratio of the center distance P between the reflector grating electrodes in the reflector grating electrode array 320 to the center distance P₀ between the IDTs in the IDT array 310 may fall into a range of [0.825, 1).

In the embodiment of the present disclosure, the reflector grating electrode array 320 may include a first reflector grating electrode array 321 and a second reflector grating electrode array 322. The first reflector grating electrode array 321 may be provided at one side of the IDT array 310, and the second reflector grating electrode array 322 may be provided at the other side of the IDT array 310. A center distance P₁ between reflector grating electrodes in the first reflector grating electrode array 321 may be less than the center distance P₀ between the IDTs in the IDT array 310. A center distance P₂ between reflector grating electrodes in the second reflector grating electrode array 322 may be less than the center distance P₀ between the IDTs in the IDT array 310. Optionally, a ratio of the center distance P₁ between the reflector grating electrodes in the first reflector grating electrode array 321 to the center distance P₀ between the IDTs in the IDT array 310 may fall into the range of [0.825, 1). A ratio of the center distance P₂ between the reflector grating electrodes in the second reflector grating electrode array 322 to the center distance P₀ between the IDTs in the IDT array 310 may fall into the range of [0.825, 1).

In an optional implementation, the center distance between the reflector grating electrodes in the first reflector grating electrode array 321 may be the same as the center distance between the reflector grating electrodes in the second reflector grating electrode array 322, namely P₁=P₂. The center distance between the reflector grating electrodes in the first reflector grating electrode array 321 may be different from the center distance between the reflector grating electrodes in the second reflector grating electrode array 322, namely P₁≠P₂.

In an optional implementation, the IDT array 310 and the reflector grating electrode array 320 may be parallel arranged on the piezoelectric thin film 200. The first reflector grating electrode array 321 and the second reflector grating electrode array 322 may be respectively provided at a left side and a right side of the IDT array 310. The reflector grating electrode array 320 may be shorted, and may also be disconnected. There is a slant angle θ between an extension direction of the IDT array 310 and a normal direction of the electrode array 300, as well as between an extension direction of the reflector grating electrode array 320 and the normal direction of the electrode array. The slant angle is less than a preset threshold. Optionally, the preset threshold may be 10°. The IDT array 310 and the reflector grating electrode array 320 are provided on the piezoelectric thin film 200 at the slant angle, which can increase the Q and suppress the spurious wave.

In the embodiment of the present disclosure, the substrate 100 may be made of SiC, and the piezoelectric thin film 200 may be made of LiNbO₃ and LiTaO₃.

In the embodiment of the present disclosure, the dielectric layer 400 may be made of a nonmetal material such as SiOₓ, Si₃N₄, AlN or Al₂O₃. This can facilitate the material preparation process, and can further increase the Q of the resonator or improve the temperature stability of the device.

With the structure of the resonator provided by the embodiment of the present disclosure, by reducing the center distance between the reflector grating electrodes in the reflector grating electrode array 320, a reflective frequency range of the reflector grating electrode array 320 can be improved, thereby suppressing the spurious mode of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency. The IDT array 310 and the reflector grating electrode array 320 are provided on the piezoelectric thin film 200 at the slant angle, which can increase the Q and suppress the spurious wave. The dielectric layer 400 is provided on the substrate 100, which can further increase the Q of the resonator or improve the temperature stability of the device.

The following describes a specific embodiment of a structure of an LL-SAW resonator in the present disclosure. FIG. 10 is a fourth schematic structural view of a resonator according to an embodiment of the present disclosure. This specification provides a composition structure as shown in the embodiments or in the accompanying drawings, but more or fewer modules or components may be included based on conventional or non-creative efforts. The composition structure listed in the embodiments is only one of numerous composition structures and is not a unique composition structure. In actual execution, the composition structure shown in the embodiments or in the accompanying drawings may be followed.

Specifically, as shown in FIG. 10, the structure of an LL-SAW resonator may include a substrate 100, a first dielectric layer 410 provided on the substrate 100, a piezoelectric thin film 200 provided on the first dielectric layer 410, an electrode array 300 provided on the piezoelectric thin film 200, and a second dielectric layer 420 provided on the electrode array 300. The electrode array 300 may include an IDT array 310 and a reflector grating electrode array 320. A center distance between reflector grating electrodes in the reflector grating electrode array 320 is less than a center distance between IDTs in the IDT array 310. By reducing the center distance between the reflector grating electrodes in the reflector grating electrode array 320, a reflective frequency range of the reflector grating electrode array 320 can be improved, thereby suppressing a spurious mode of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency.

In the embodiment of the present disclosure, a ratio of the center distance P between the reflector grating electrodes in the reflector grating electrode array 320 to the center distance P₀ between the IDTs in the IDT array 310 may fall into a range of [0.825, 1).

In the embodiment of the present disclosure, the reflector grating electrode array 320 may include a first reflector grating electrode array 321 and a second reflector grating electrode array 322. The first reflector grating electrode array 321 may be provided at one side of the IDT array 310, and the second reflector grating electrode array 322 may be provided at the other side of the IDT array 310. A center distance P₁ between reflector grating electrodes in the first reflector grating electrode array 321 may be less than the center distance P₀ between the IDTs in the IDT array 310. A center distance P₂ between reflector grating electrodes in the second reflector grating electrode array 322 may be less than the center distance P₀ between the IDTs in the IDT array 310. Optionally, a ratio of the center distance P₁ between the reflector grating electrodes in the first reflector grating electrode array 321 to the center distance P₀ between the IDTs in the IDT array 310 may fall into the range of [0.825, 1). A ratio of the center distance P₂ between the reflector grating electrodes in the second reflector grating electrode array 322 to the center distance P₀ between the IDTs in the IDT array 310 may fall into the range of [0.825, 1).

In an optional implementation, the center distance between the reflector grating electrodes in the first reflector grating electrode array 321 may be the same as the center distance between the reflector grating electrodes in the second reflector grating electrode array 322, namely P₁=P₂. The center distance between the reflector grating electrodes in the first reflector grating electrode array 321 may be different from the center distance between the reflector grating electrodes in the second reflector grating electrode array 322, namely P₁≠P₂.

In an optional implementation, the IDT array 310 and the reflector grating electrode array 320 may be parallel arranged on the piezoelectric thin film 200. The first reflector grating electrode array 321 and the second reflector grating electrode array 322 may be respectively provided at a left side and a right side of the IDT array 310. The reflector grating electrode array 320 may be shorted, and may also be disconnected. There is a slant angle θ between an extension direction of the IDT array 310 and a normal direction of the electrode array 300, as well as between an extension direction of the reflector grating electrode array 320 and the normal direction of the electrode array. The slant angle is less than a preset threshold. Optionally, the preset threshold may be 10°. The IDT array 310 and the reflector grating electrode array 320 are provided on the piezoelectric thin film 200 at the slant angle, which can increase the Q and suppress the spurious wave.

In the embodiment of the present disclosure, the substrate 100 may be made of SiC, and the piezoelectric thin film 200 may be made of LiNbO₃ and LiTaO₃.

In the embodiment of the present disclosure, the first dielectric layer 410 may be made of a nonmetal material such as SiOₓ, Si₃N₄, AlN or Al₂O₃. The second dielectric layer 420 may be made of a nonmetal material such as SiOₓ, Si₃N₄, AlN or Al₂O₃. This can facilitate the material preparation process, and can further increase the Q of the resonator or improve the temperature stability of the device.

With the structure of an LL-SAW resonator provided by the embodiment of the present disclosure, by reducing the center distance between the reflector grating electrodes in the reflector grating electrode array 320, a reflective frequency range of the reflector grating electrode array 320 can be improved, thereby suppressing the spurious mode of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency. The IDT array and the reflector grating electrode array 320 are provided on the piezoelectric thin film 200 at the slant angle, which can increase the Q and suppress the spurious wave. The dielectric layer 400 is provided on the substrate 100, which can further increase the Q of the resonator or improve the temperature stability of the device.

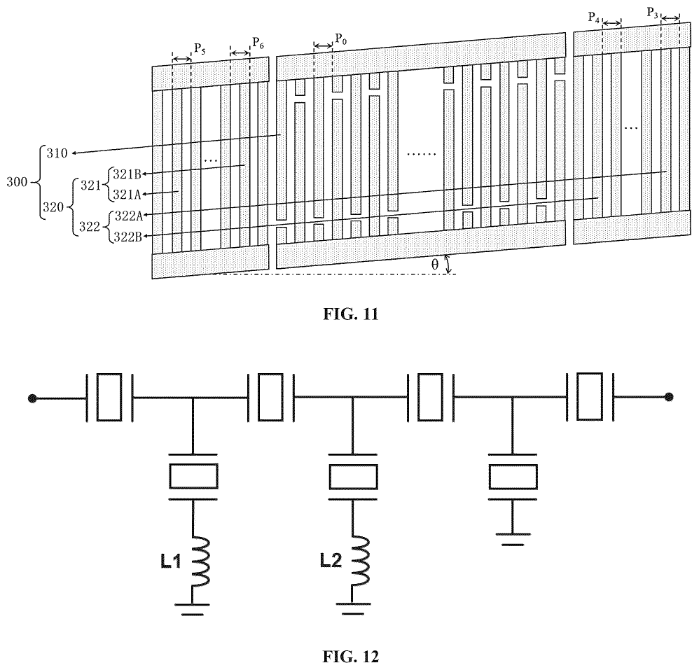

The following describes a specific embodiment of a structure of an LL-SAW resonator in the present disclosure. FIG. 11 is a second schematic top view of a resonator according to an embodiment of the present disclosure. This specification provides a composition structure as shown in the embodiments or in the accompanying drawings, but more or fewer modules or components may be included based on conventional or non-creative efforts. The composition structure listed in the embodiments is only one of numerous composition structures and is not a unique composition structure. In actual execution, the composition structure shown in the embodiments or in the accompanying drawings may be followed.

Specifically, as shown in FIG. 11, the structure of an LL-SAW resonator may include a substrate 100, a piezoelectric thin film 200 provided on the substrate 100, and an electrode array 300 provided on the piezoelectric thin film 200. The electrode array 300 may include an IDT array 310 and a reflector grating electrode array 320. A center distance between reflector grating electrodes in the reflector grating electrode array 320 is less than a center distance between IDTs in the IDT array 310. By reducing the distance between the reflector grating electrodes in the reflector grating electrode array 320, a reflective frequency range of the reflector grating electrode array 320 can be improved, thereby suppressing a spurious wave of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency.

In the embodiment of the present disclosure, a ratio of the center distance P between the reflector grating electrodes in the reflector grating electrode array 320 to the center distance P₀ between the IDTs in the IDT array 310 may fall into a range of [0.825, 1).

In the embodiment of the present disclosure, the reflector grating electrode array 320 may include a first reflector grating electrode array 321 and a second reflector grating electrode array 322. The first reflector grating electrode array 321 may include a first reflector grating electrode sub-array 321A and a second reflector grating electrode sub-array 321B. The second reflector grating electrode array 322 may include a third reflector grating electrode sub-array 322A and a fourth reflector grating electrode sub-array 322B. The first reflector grating electrode sub-array 321A and the second reflector grating electrode sub-array 321B may be provided at one side of the IDT array 310, and the third reflector grating electrode sub-array 322A and the fourth reflector grating electrode sub-array 322B may be provided at the other side of the IDT array. A center distance P₅ between reflector grating electrodes in the first reflector grating electrode sub-array 321A may be less than the center distance P₀ between the IDTs in the IDT array 310. A center distance P₆ between reflector grating electrodes in the second reflector grating electrode sub-array 321B may be less than the center distance P₀ between the IDTs in the IDT array 310. A center distance P₃ between reflector grating electrodes in the third reflector grating electrode sub-array 322A may be less than the center distance P₀ between the IDTs in the IDT array 310. A center distance P₄ between reflector grating electrodes in the fourth reflector grating electrode sub-array 322B may be less than the center distance P₀ between the IDTs in the IDT array 310. The center distance between the reflector grating electrodes in the first reflector grating electrode sub-array 321A, the center distance between the reflector grating electrodes in the second reflector grating electrode sub-array 321B, the center distance between the reflector grating electrodes in the third reflector grating electrode sub-array 322A, and the center distance between the reflector grating electrodes in the fourth reflector grating electrode sub-array 322B are different. Optionally, a ratio of the center distance P₅ between the reflector grating electrodes in the first reflector grating electrode sub-array 321A to the center distance P₀ between the IDTs in the IDT array 310 may fall into a range of [0.825, 1). A ratio of the center distance P₆ between the reflector grating electrodes in the second reflector grating electrode sub-array 321B to the center distance P₀ between the IDTs in the IDT array 310 may fall into a range of [0.825, 1). A ratio of the center distance P₃ between the reflector grating electrodes in the third reflector grating electrode sub-array 322A to the center distance P₀ between the IDTs in the IDT array 310 may fall into a range of [0.825, 1). A ratio of the center distance P₄ between the reflector grating electrodes in the fourth reflector grating electrode sub-array 322B to the center distance P₀ between the IDTs in the IDT array 310 may fall into a range of [0.825, 1).

In an optional implementation, the IDT array 310 and the reflector grating electrode array 320 may be parallel arranged on the piezoelectric thin film 200. The reflector grating electrode array 320 may be shorted, and may also be disconnected. There is a slant angle θ between an extension direction of the IDT array 310 and a normal direction of the electrode array 300, as well as between an extension direction of the reflector grating electrode array 320 and the normal direction of the electrode array. The slant angle θ is less than a preset threshold. Optionally, the preset threshold may be 10°. The IDT array 310 and the reflector grating electrode array 320 are provided on the piezoelectric thin film 200 at the slant angle, which can increase the Q and suppress the spurious wave.

In the embodiment of the present disclosure, the substrate 100 may be made of SiC, and the piezoelectric thin film 200 may be made of LiNbO₃ and LiTaO₃.

The following describes a specific embodiment of a filter provided by the present disclosure. FIG. 12 is a schematic structural view of another filter according to an embodiment of the present disclosure. The filter may include a plurality of resonators. The resonators each may be provided with the structure shown in FIG. 1. The plurality of resonators may be electrically connected to a passive reactor element based on a preset topological structure to form the filter. The preset topological structure includes a ladder type, a transversal, a lattice type, etc. As shown in FIG. 12, the plurality of resonators may be formed into the filter together with an inductor element.

With the structure of an LL-SAW resonator provided by the embodiment of the present disclosure, by reducing the center distance between the reflector grating electrodes in the reflector grating electrode array 320, a reflective frequency range of the reflector grating electrode array 320 can be improved, thereby suppressing the spurious mode of the LL-SAW, and improving performance of the resonator. Improving the reflective frequency range of the reflector grating electrode array 320 is to shift a maximum reflective frequency and a minimum reflective frequency of the reflector grating electrode array 320 to a higher frequency.

It should be noted that an order of the embodiments of the present disclosure is only for description and does not represent superiority or inferiority of the embodiments. Moreover, the specific embodiments are described in this specification, and other embodiments are also within the scope of the attached claims. In some cases, the actions or steps described in the claims may be performed in sequences different from those in the embodiments, and expected results can still be achieved. In addition, the processes depicted in the accompanying drawings do not necessarily require the specific orders or sequential orders shown for achieving the expected results. In some implementations, multitasking and parallel processing are also possible or may be advantageous.

The embodiments in this specification are described in a progressive manner. For same or similar parts between the embodiments, reference may be made to each other. Each embodiment focuses on a difference from other embodiments. For embodiments of an apparatus and an electronic device, since they are basically similar to the method embodiment, the description is relatively simple, and reference can be made to the description of the method embodiment.

The descriptions above are preferred implementations of the present disclosure. It should be noted that for a person of ordinary skill in the art, various improvements and modifications can be made without departing from the principles of the present disclosure. These improvements and modifications should also be regarded as falling into the protection scope of the present disclosure.

1. A structure of a longitudinal leaky surface acoustic wave (LL-SAW) resonator, comprising:
a substrate, wherein the substrate is made of silicon carbide (SiC);
a piezoelectric thin film provided on the substrate, wherein the piezoelectric thin film is made of lithium niobate (LiNbO₃) or lithium tantalate (LiTaO₃); and
an electrode array provided on the piezoelectric thin film, wherein the electrode array comprises an interdigital transducer (IDT) array and a reflector grating electrode array, and a center distance between reflector grating electrodes in the reflector grating electrode array is less than a center distance between IDTs in the IDT array.

2. The structure according to claim 1, wherein a ratio of the center distance between the reflector grating electrodes in the reflector grating electrode array to the center distance between the IDTs in the IDT array falls into a range of [0.825, 1).

3. The structure according to claim 1, wherein the reflector grating electrode array comprises a first reflector grating electrode array and a second reflector grating electrode array;
the first reflector grating electrode array is provided at one side of the IDT array, and the second reflector grating electrode array is provided at the other side of the IDT array;
a center distance between reflector grating electrodes in the first reflector grating electrode array is the same as a center distance between reflector grating electrodes in the second reflector grating electrode array; or,
the center distance between the reflector grating electrodes in the first reflector grating electrode array is different from the center distance between the reflector grating electrodes in the second reflector grating electrode array.

4. The structure according to claim 3, wherein
the first reflector grating electrode array comprises a first reflector grating electrode sub-array and a second reflector grating electrode sub-array;
the second reflector grating electrode array comprises a third reflector grating electrode sub-array and a fourth reflector grating electrode sub-array;
a center distance between reflector grating electrodes in the first reflector grating electrode sub-array is different from a center distance between reflector grating electrodes in the second reflector grating electrode sub-array; and
a center distance between reflector grating electrodes in the third reflector grating electrode sub-array is different from a center distance between reflector grating electrodes in the fourth reflector grating electrode sub-array.

5. The structure according to claim 4, wherein the center distance between the reflector grating electrodes in the first reflector grating electrode sub-array, the center distance between the reflector grating electrodes in the second reflector grating electrode sub-array, the center distance between the reflector grating electrodes in the third reflector grating electrode sub-array, and the center distance between the reflector grating electrodes in the fourth reflector grating electrode sub-array are different.

6. The structure according to claim 1, wherein there is a slant angle between an extension direction of the IDT array and a normal direction of the electrode array, as well as between an extension direction of the reflector grating electrode array and the normal direction of the electrode array; and
the slant angle is less than a preset threshold; and the preset threshold is 10°.

7. The structure according to claim 1, further comprising:
a dielectric layer provided on the substrate,
wherein the dielectric layer is made of silicon oxide (SiOₓ), silicon nitride (Si₃N₄), aluminum nitride (AlN), or aluminum oxide (Al₂O₃).

8. The structure according to claim 1, further comprising:
a dielectric layer provided on the electrode array,
wherein the dielectric layer is made of SiOₓ, Si₃N₄, AlN, or Al₂O₃.

9. The structure according to claim 1, further comprising:
a first dielectric layer provided on the electrode array; and
a second dielectric layer provided on the substrate,
wherein the first dielectric layer is made of SiOₓ, Si₃N₄, AlN, or Al₂O₃; and
the second dielectric layer is made of the SiOₓ, the Si₃N₄, the AlN, or the Al₂O₃.

10. A filter, comprising a plurality of resonators, wherein the resonators each are provided with the structure of a longitudinal leaky surface acoustic wave (LL-SAW) resonator according to claim 1;
the plurality of resonators are cascaded, bridged, or coupled based on a preset topological structure; or,
the plurality of resonators are cascaded or bridged with an external capacitor element and an external inductor element.

11. A filter, comprising a plurality of resonators, wherein the resonators each are provided with the structure of a longitudinal leaky surface acoustic wave (LL-SAW) resonator according to claim 2;
the plurality of resonators are cascaded, bridged or coupled based on a preset topological structure; or,
the plurality of resonators are cascaded or bridged with an external capacitor element and an external inductor element.

12. A filter, comprising a plurality of resonators, wherein the resonators each are provided with the structure of a longitudinal leaky surface acoustic wave (LL-SAW) resonator according to claim 3;
the plurality of resonators are cascaded, bridged or coupled based on a preset topological structure; or,
the plurality of resonators are cascaded or bridged with an external capacitor element and an external inductor element.

13. A filter, comprising a plurality of resonators, wherein the resonators each are provided with the structure of a longitudinal leaky surface acoustic wave (LL-SAW) resonator according to claim 4;
the plurality of resonators are cascaded, bridged or coupled based on a preset topological structure; or,
the plurality of resonators are cascaded or bridged with an external capacitor element and an external inductor element.

14. A filter, comprising a plurality of resonators, wherein the resonators each are provided with the structure of a longitudinal leaky surface acoustic wave (LL-SAW) resonator according to claim 5;
the plurality of resonators are cascaded, bridged or coupled based on a preset topological structure; or,
the plurality of resonators are cascaded or bridged with an external capacitor element and an external inductor element.

15. A filter, comprising a plurality of resonators, wherein the resonators each are provided with the structure of a longitudinal leaky surface acoustic wave (LL-SAW) resonator according to claim 6;
the plurality of resonators are cascaded, bridged or coupled based on a preset topological structure; or,
the plurality of resonators are cascaded or bridged with an external capacitor element and an external inductor element.

16. A filter, comprising a plurality of resonators, wherein the resonators each are provided with the structure of a longitudinal leaky surface acoustic wave (LL-SAW) resonator according to claim 7;
the plurality of resonators are cascaded, bridged or coupled based on a preset topological structure; or,
the plurality of resonators are cascaded or bridged with an external capacitor element and an external inductor element.

17. A filter, comprising a plurality of resonators, wherein the resonators each are provided with the structure of a longitudinal leaky surface acoustic wave (LL-SAW) resonator according to claim 8;
the plurality of resonators are cascaded, bridged or coupled based on a preset topological structure; or,
the plurality of resonators are cascaded or bridged with an external capacitor element and an external inductor element.

18. A filter, comprising a plurality of resonators, wherein the resonators each are provided with the structure of a longitudinal leaky surface acoustic wave (LL-SAW) resonator according to claim 9;
the plurality of resonators are cascaded, bridged or coupled based on a preset topological structure; or,
the plurality of resonators are cascaded or bridged with an external capacitor element and an external inductor element.
